(19) United States
(12) Patent Application Publication
(10) Pub. No.: US 2024/0057443 A1
(43) Pub. Date: Feb. 15, 2024

(54) DISPLAY PANEL

(71) Applicant: Shenzhen China Star Optoelectronics Semiconductor Display Technology Co., Ltd., Shenzhen (CN)

(72) Inventors: Jinchuan Li, Shenzhen (CN); Ying Liu, Shenzhen (CN); Wendong Lian, Shenzhen (CN)

(21) Appl. No.: 17/621,657

(22) PCT Filed: Dec. 10, 2021
(86) PCT No.: PCT/CN2021/137034

§ 371 Date: Dec. 21, 2021

(30) Foreign Application Priority Data
Nov. 26, 2021 (CN) 202111417504.X

(51) Int. Cl. H10K 59/80

(52) U.S. Cl. CPC H10K 59/872; H10K 59/874

(57) ABSTRACT

A display panel is provided. The display panel includes a first substrate, a second substrate, and a frame disposed between the first substrate and the second substrate. The first substrate includes a first dam, and the second substrate includes a second dam. The first dam protrudes toward the second substrate, the second dam protrudes toward the first substrate, the first dam and the second dam are arranged adjacent to each other, and the first dam and the second dam are both embedded in the frame.

The present disclosure priority to Chinese Patent Application No. 202111417504.X, entitled “DISPLAY PANEL” filed with the China National Intellectual Property Administration on Nov. 26, 2021, which is incorporated herein by reference in its entirety.

### FIELD OF INVENTION

The present disclosure relates to the field of display technologies, and in particular, to a display panel.

### BACKGROUND OF INVENTION

An organic light emitting diode (OLED) is a current-mode OLED, which is widely used in the flexible display device industry by virtue of a high brightness and low power consumption. Compared with traditional liquid crystal, organics are prone to aging. Therefore, in order to prolong the lifetime of the materials, a packaging structure having strong water resistance is usually required to reduce the risk of moisture intrusion. The current mainstream rigid packaging generally means packaging a substrate with a thin film. A sealant (dam) is used at an edge to bond a substrate to a cover plate (cover glass) and seal the substrate and the cover plate. For a large-sized device, a filler is added between the cover plate and the substrate. Due to the strong water resistance of the cover plate, the edge generally first fails. That is to say, the osmotic pressure causes moisture to penetrate the dam into the interior until the package fails.

### SUMMARY OF INVENTION

### Technical Problem

The current display device has a technical problem that moisture penetrates the edge of the device and causes a packaging failure.

### Technical Solution

The present disclosure provides a display panel, to alleviate a technical problem of a current display device that moisture penetrates an edge of the device and causes a packaging failure.

The present disclosure provides a display panel, including:
a first substrate including a display area having a plurality of display units and a non-display area adjacent to the display area and close to an edge of the first substrate, wherein a first dam is disposed in an area of the first substrate corresponding to the non-display area;
a second substrate disposed opposite to the first substrate, wherein a second dam is disposed in an area of the second substrate corresponding to the non-display area, the first dam protrudes toward the second substrate, the second dam protrudes toward the first substrate, and the first dam and the second dam are arranged adjacent to each other; and
a frame disposed between the first substrate and the second substrate and corresponding to the non-display area, wherein the first dam and the second dam are both embedded in the frame.

In the display panel of the present disclosure, a projection of the first dam on the first substrate is annular, and a projection of the second dam on the second substrate is annular.

In the display panel of the present disclosure, the first dam and the second dam are both disposed along an edge of the display panel in a circle.

In the display panel of the present disclosure, the first dam includes a square circular structure or an annular structure, and the second dam includes a square circular structure or an annular structure.

In the display panel of the present disclosure, a projection of the first dam on the second substrate and the second dam may partially overlap or do not overlap.

In the display panel of the present disclosure, a height of the first dam is less than a total thickness of the frame and is greater than half of the thickness of the frame, and a height of the second dam is also less than the total thickness of the frame and is greater than half of the thickness of the frame.

In the display panel of the present disclosure, the first dam includes a first sub-dam and a second sub-dam disposed parallel to each other. The second dam is disposed between the first sub-dam and the second sub-dam.

In the display panel of the present disclosure, the first sub-dam includes a plurality of first dam areas discontinuously disposed and a first discontinuous area located between two adjacent first dam areas, and the second sub-dam includes a plurality of second dam areas discontinuously disposed and a second discontinuous area located between two adjacent second dam areas.

The second discontinuous area corresponds to the first dam area, and the first discontinuous area corresponds to the second dam area.

In the display panel of the present disclosure, the second dam includes a third sub-dam and a fourth sub-dam disposed parallel to each other, and the first dam is disposed between the third sub-dam and the fourth sub-dam.

In the display panel of the present disclosure, the third sub-dam includes a plurality of third dam areas discontinuously disposed and a third discontinuous area located between two adjacent third dam areas, and the fourth sub-dam includes a plurality of fourth dam areas discontinuously disposed and a fourth discontinuous area located between two adjacent fourth dam areas.

The fourth discontinuous area corresponds to the third dam area, and the third discontinuous area corresponds to the fourth dam area.

In the display panel of the present disclosure, a cross-sectional shape of the first dam along a plane perpendicular to the first substrate includes a trapezoid or a triangle.

In the display panel of the present disclosure, a cross-sectional shape of the second dam along a plane perpendicular to the second substrate includes a trapezoid or a triangle.

In the display panel of the present disclosure, the first dam includes a first dam body and a first water blocking layer covering the first dam body, and the first water blocking layer is located between the first dam body and the frame.

In the display panel of the present disclosure, the second dam includes a second dam body and a second water blocking layer covering the second dam body, wherein the second water blocking layer is located between the second dam body and the frame.

In the display panel of the present disclosure, the first dam body includes one or more of magnesium oxide, calcium oxide, magnesium chloride, or silica gel, and the first water blocking layer includes one or more of silicon nitride, silicon oxynitride, or aluminum oxide.

In the display panel of the present disclosure, the second dam body includes one or more of magnesium oxide, calcium oxide, magnesium chloride, or silica gel, and the second water blocking layer includes one or more of silicon nitride, silicon oxynitride, or aluminum oxide.

In the display panel of the present disclosure, the frame includes a plastic frame and a desiccant distributed inside or on a surface of the plastic frame.

In the display panel of the present disclosure, the desiccant includes one or more of magnesium oxide, calcium oxide, magnesium chloride, or silica gel.

In the display panel of the present disclosure, the frame is disposed along the non-display area and around the edge of the display panel in a circle.

The present disclosure further provides a display panel, including:
a first substrate including a display area having a plurality of display units and a non-display area adjacent to the display area and close to an edge of the first substrate, wherein a first dam is disposed in an area of the first substrate corresponding to the non-display area;
a second substrate disposed opposite to the first substrate, wherein a second dam is disposed in an area of the second substrate corresponding to the non-display area, the first dam protrudes toward the second substrate, the second dam protrudes toward the first substrate, and the first dam and the second dam are arranged adjacent to each other; and
a frame disposed between the first substrate and the second substrate and corresponding to the non-display area, wherein the first dam and the second dam are both embedded in the frame; wherein
a height of the first dam is less than a total thickness of the frame and is greater than half of the thickness of the frame, a height of the second dam is also less than the total thickness of the frame and is greater than half of the thickness of the frame, and a projection of the first dam on the second substrate and the second dam may partially overlap or do not overlap.

### Beneficial Effects

Beneficial effects of the present disclosure are as follows: The present disclosure provides the display panel. The display panel includes the first substrate, the second substrate disposed opposite to the first substrate, and the frame disposed between the first substrate and the second substrate and corresponding to the non-display area, the first dam is disposed in the area of the first substrate corresponding to the non-display area, the second dam is disposed in the area of the second substrate corresponding to the non-display area, the first dam protrudes toward the second substrate, the second dam protrudes toward the first substrate, the first dam and the second dam are arranged adjacent to each other, and the first dam and the second dam are both embedded in the frame. According to the present disclosure, the first dam and the second dam corresponding to the non-display area at an edge of the display panel are respectively disposed on the first substrate and the second substrate, and the first dam and the second dam are arranged adjacent to each other, and are both embedded in the frame of the display panel. By means of the embedded structure of the first dam, the second dam, and the frame, the moisture blocking performance of the edge of the display panel is enhanced, the moisture intruding path into the display panel is extended, and the risk of failure of the packaging at the edge of the display panel is reduced.

### BRIEF DESCRIPTION OF DRAWINGS

To describe the technical solutions in the embodiments or in the related art more clearly, the following briefly describes the accompanying drawings required for describing the embodiments or the related art. Apparently, the accompanying drawings in the following description show merely some embodiments of the present disclosure, and a person of ordinary skill in the art may derive other drawings according to such accompanying drawings without creative efforts.

FIG. 1 is a schematic top view of a structure of a first display panel according to an embodiment of the present disclosure.

FIG. 2 is a schematic partial cross-sectional view of the structure of the first display panel according to an embodiment of the present disclosure.

FIG. 3 is a schematic partial cross-sectional view of a structure of a second display panel according to an embodiment of the present disclosure.

FIG. 4 is a schematic top view of a structure of a first substrate in the second display panel according to an embodiment of the present disclosure.

FIG. 5 is a schematic partial cross-sectional view of a structure of a third display panel according to an embodiment of the present disclosure.

FIG. 6 is a schematic top view of a structure of a second substrate in the third display panel according to an embodiment of the present disclosure.

### DETAILED DESCRIPTION OF PREFERRED EMBODIMENTS

The following description of various embodiments is provided to exemplify the specific embodiments for implementation of the present disclosure with reference to accompanying drawings. The directional terms mentioned in the present disclosure, such as “above”, “below”, “front”, “back”, “left”, “right”, “inside”, “outside”, and “side”, merely refer to the directions in the accompanying drawings. Therefore, the used direction terms are intended to describe and understand the present disclosure, but are not intended to limit the present disclosure. In the figures, structurally similar units are denoted by the same reference numerals.

The present disclosure provides a display panel. The display panel includes a first substrate, a second substrate disposed opposite to the first substrate, and a frame disposed between the first substrate and the second substrate and corresponding to a non-display area, a first dam is disposed in an area of the first substrate corresponding to the non-display area, a second dam is disposed in an area of the second substrate corresponding to the non-display area, the first dam protrudes toward the second substrate, the second dam protrudes toward the first substrate, the first dam and the second dam are arranged adjacent to each other, and the first dam and the second dam are both embedded in the frame. According to the embodiments of the present disclosure, the first dam and the second dam corresponding to the non-display area at an edge of the display panel are respectively disposed on the first substrate and the second substrate, and the first dam and the second dam are arranged adjacent to each other, and are both embedded in the frame of the display panel. By means of the embedded structure of the first dam, the second dam, and the frame, the moisture blocking performance of the edge of the display panel is enhanced, the moisture intruding path into the display panel is extended, and the risk of failure of the packaging at the edge of the display panel is reduced.

The structural characteristics and the functional characteristics of the display panel provided in the embodiments of the present disclosure are described below with reference to the drawings.

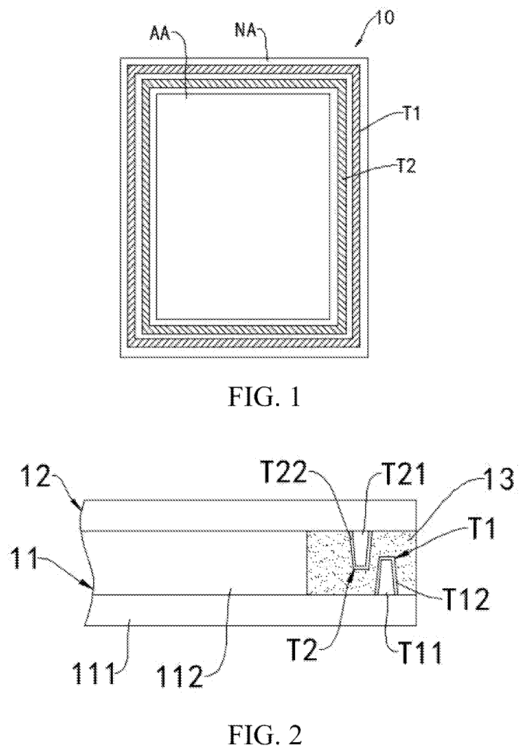

In an embodiment, referring to FIG. 1 and FIG. 2, FIG. 1 is a schematic top view of a structure of a first display panel according to an embodiment of the present disclosure, and FIG. 2 is a schematic partial cross-sectional view of the structure of the first display panel according to an embodiment of the present disclosure.

The present embodiment provides a display panel 10. The display panel 10 may be an organic light emitting diode (OLED) display panel, a micro light emitting diode display panel (micro LED), or other types of display panels. The first display panel 10 includes a first substrate 11 and a second substrate 12 disposed opposite to the first substrate 11. Optionally, the first substrate 11 may be a substrate including a plurality of display units for realizing the display function of the display panel 10, such as an OLED array display substrate. The second substrate 12 may be a substrate disposed along a light-exit surface of the first substrate 11 and configured to package a surface of the first substrate 11, such as a glass cover-plate. In some other embodiments, the above structures of the first substrate 11 and the second substrate 12 may be transposed.

In detail, the first substrate 11 has a display area AA and a non-display area NA adjacent to the display area AA, and a plurality of display units are disposed in an area of the first substrate 11 corresponding to the display area AA to realize the display function. The non-display area NA is close to an edge of the display panel 10, and has disposed therein a plurality of functional elements configured to help display units in the display area AA perform displaying and a packaging structure configured to package the edge of the display panel 10. It may be understood that the display area AA and the non-display area NA of the first substrate 11 correspond to the display area and the non-display area of the display panel 10 respectively.

The first substrate 11 includes a base substrate 111 and a display function layer 112 disposed on the base substrate 111. The base substrate 111 may be a substrate made of glass, polyimide, or the like. The display function layer 112 may include structures such as a driving circuit layer and a light emitting layer configured to realize the display function of the first substrate 11. A plurality of circuits, traces, and components configured to provide driving signals to the light emitting layer are disposed in the driving circuit layer. The light emitting layer includes devices such as OLEDs for emitting light. The LEDs in the light emitting layer that can emit light of a plurality of colors may be arranged according to a designated arrangement rule to realize color displaying.

The second substrate 12 is disposed on the light-exit surface of the first substrate 11 and covers the light emitting layer and at least part of the non-display area NA in the first substrate 11. The second substrate 12 is configured to package and protect the light-exit surface of the first substrate 11, so as to prevent moisture from intruding into the display panel 10 through the light-exit surface of the first substrate 11 and prevent external mechanical damage to the light-exit surface of the first substrate 11. The second substrate 12 may be made of glass or the like.

The display panel 10 further includes a frame 13 disposed between the first substrate 11 and the second substrate 12. The frame 13 is disposed in an area corresponding to the non-display area NA. The frame 13 is disposed along the non-display area NA and around the edge of the display panel 10 in a circle, to realize the packaging of the edge of the display panel 10. The frame 13 seals sides of the display panel 10, so as to prevent partial moisture from intruding into the display panel 10 through the sides of the display panel 10. Optionally, the frame 13 may be made of a flexible rubber material, such as a resin material.

Further, a first dam T1 is disposed on a side of the first substrate 11 facing the second substrate 12. The first dam T1 protrudes toward the second substrate 12 and is disposed corresponding to the non-display area NA. A second dam T2 is disposed on a side of the second substrate 12 facing the first substrate 11. The second dam T2 protrudes toward the first substrate 11 and is disposed corresponding to the non-display area NA. The first dam T1 is adjacent to the second dam T2. The first dam T1 and the second dam T2 are both embedded in the frame 13. In the present embodiment, the first dam T1 and the second dam T2 are arranged adjacent to each other, and are both embedded in the frame 13 of the display panel 10. By means of the embedded structure of the first dam T1, the second dam T2, and the frame 13, the moisture blocking performance of the edge of the display panel 10 is enhanced. When the moisture intrudes through the sides of the display panel 10, the moisture is required to bypass the first dam T1 and the second dam T2. Therefore, the moisture path into the display panel 10 is extended, and the risk of failure of the packaging at the edge of the display panel 10 is reduced.

Further, a projection of the first dam T1 on the first substrate 11 is annular, and a projection of the second dam T2 on the second substrate 12 is annular. That is to say, the first dam T1 and the second dam T2 are both disposed along the edge of the display panel 10 in a circle, and form, with the frame 13 disposed in a circle, a complete circular structure sealing the edge of the display panel 10. Optionally, the first dam T1 and the second dam T2 may be a square circular structure or an annular structure corresponding to the appearance characteristic of the display panel 10.

A cross-sectional shape of the first dam T1 along a plane perpendicular to the first substrate 11 includes a trapezoid or a triangle, and a cross-sectional shape of the second dam T2 along a plane perpendicular to the second substrate 12 includes a trapezoid or a triangle. It may be understood that, the first dam T1 and the second dam T2 having the above shape characteristic are more easily embedded into the frame 13. During manufacturing of the display panel 10, the frame 13 may be manufactured on any substrate (the first substrate 11 or the second substrate 12), and the dam on the substrate is spontaneously embedded into the frame 13. Then the other substrate is mated with the substrate. The dam on the other substrate may be directly pressed into the frame 13 to realize embodiment.

The projection of the first dam T1 on the second substrate 12 and the second dam T2 may partially overlap or do not overlap. A height of the first dam T1 is less than a total thickness of the frame 13 and is greater than half of the thickness of the frame 13. A height of the second dam T2 is also less than the total thickness of the frame 13 and is greater than half of the thickness of the frame 13. By means of the above structural characteristics, the first dam T1 and the second dam T2 are completely embedded into the frame 13. Therefore, when external moisture intrudes into the display panel 10 through the sides of the display panel 10, the external moisture is required to bypass both the first dam T1 and the second dam T2. In this way, the moisture intruding path is extended, and the moisture resistance performance of the display panel 10 is enhanced.

Further, the first dam T1 includes a first dam body T11 and a first water blocking layer T12 covering the first dam body T11. The first water blocking layer T12 is located between the first dam body T11 and the frame 13. The second dam T2 includes a second dam body T21 and a second water blocking layer T22 covering the second dam body T21. The second water blocking layer T22 is located between the second dam body T21 and the frame 13. In addition to main materials, such as rubber, the first dam body T11 and the second dam body T21 further include some desiccant materials, such as one or more of magnesium oxide, calcium oxide, magnesium chloride, or silica gel. By means of the desiccant materials, the moisture blocking performance of the first dam T1 and the second dam T2 is further enhanced.

The first water blocking layer T12 may be a water blocking material coated or deposited on a side of a surface of the first dam body T11, and the water blocking material may be one or more of silicon nitride, silicon oxynitride, or aluminum oxide. The second water blocking layer T22 may be a water blocking material coated or deposited on a side of a surface of the second dam body T21, and the water blocking material may also be one or more of silicon nitride, silicon oxynitride, or aluminum oxide. In the present embodiment, the first water blocking layer T12 and the second water blocking layer T22 are respectively disposed on the surfaces of the first dam body T11 and the second dam body T21. Therefore, the moisture blocking performance of the first dam T1 and the second dam T2 is further enhanced.

Further, the frame 13 includes a plastic frame and a desiccant distributed inside or on a surface of the plastic frame. The desiccant includes one or more of magnesium oxide, calcium oxide, magnesium chloride, or silica gel. In the present embodiment, by adding the desiccant to the frame 13, the moisture blocking performance of the frame 13 is enhanced. Therefore, the packaging at the edge of the display panel 10 is further enhanced, and the risk of failure of the packaging at the edge is reduced.

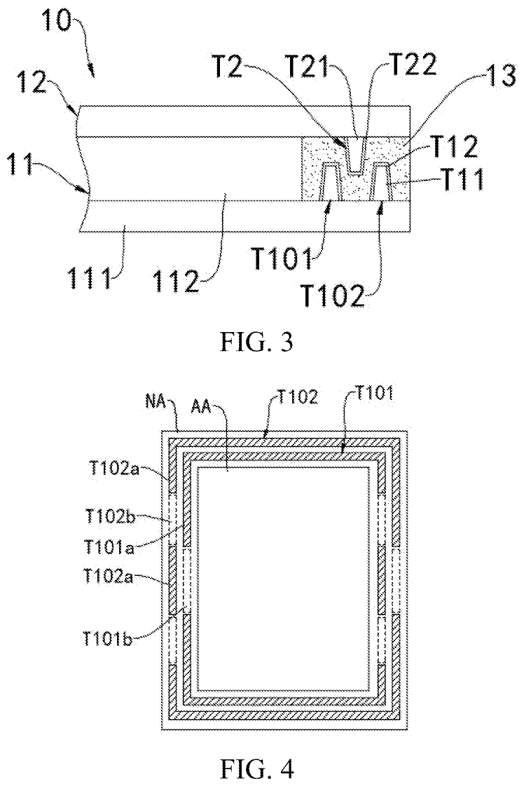

In another embodiment, referring to FIG. 3 and FIG. 4, FIG. 3 is a schematic partial cross-sectional view of a structure of a second display panel according to an embodiment of the present disclosure, and FIG. 4 is a schematic top view of a structure of a first substrate in the second display panel according to an embodiment of the present disclosure. It may be understood that the display panel provided in the present embodiment has a same or similar structure as the display panel described in the above embodiment. The features of the display panel provided in the present embodiment are described below. For details not provided, refer to the description of the above embodiment.

The present embodiment provides a display panel 10. The display panel includes a first substrate 11 and a second substrate 12 disposed opposite to the first substrate 11. The first substrate 11 includes a base substrate 111 and a display function layer 112 disposed on the base substrate 111. The second substrate 12 is disposed on a light-exit surface of the first substrate 11.

The first substrate 11 has a display area AA and a non-display area NA adjacent to the display area AA. A plurality of display units are disposed in an area of the first substrate 11 corresponding to the display area AA to realize the display function. The non-display area NA is close to an edge of the display panel 10, and has disposed therein a plurality of functional elements configured to help display units in the display area AA perform displaying and a packaging structure configured to package the edge of the display panel 10.

The display panel 10 further includes a frame 13 disposed between the first substrate 11 and the second substrate 12. The frame 13 is disposed in the non-display area NA. The frame 13 is disposed along the non-display area NA and around the edge of the display panel 10 in a circle, to realize the packaging of the edge of the display panel 10.

A first dam is disposed on a side of the first substrate 11 facing the second substrate 12. The first dam includes a first sub-dam T101 and a second sub-dam T102 disposed parallel to each other. The first sub-dam T101 and the second sub-dam T102 both protrude toward the second substrate 12 and are disposed corresponding to the non-display area NA. A second dam T2 is disposed on a side of the second substrate 12 facing the first substrate 11. The second dam T2 protrudes toward the first substrate 11 and is disposed corresponding to the non-display area NA. The second dam T2 is disposed between the first sub-dam T101 and the second sub-dam T102, and the first sub-dam T101, the second sub-dam T102, and the second dam T2 are all embedded in the frame 13, so as to enhance the moisture blocking performance of the edge of the display panel 10 and reduce the risk of failure of the packaging at the edge of the display panel 10.

The first sub-dam T101 includes a plurality of first dam areas T101a discontinuously disposed and a first discontinuous area T101b located between two adjacent first dam areas T101a. The second sub-dam T102 includes a plurality of second dam areas T102a discontinuously disposed and a second discontinuous area T102b located between two adjacent second dam areas T102a. The second discontinuous area T102b corresponds to the first dam area T101a, and the first discontinuous area T101b corresponds to the second dam area T102a. It may be understood that, the first sub-dam T101 and the second sub-dam T102 are both discontinuously distributed structures, the first dam area T101a and the second dam area T102a are respectively physical distribution areas of the first sub-dam T101 and the second sub-dam T102, and the first discontinuous area T101b and the second discontinuous area T102b are respectively physical discontinuous areas of the first sub-dam T101 and the second sub-dam T102. In the present embodiment, the first sub-dam T101 and the second sub-dam T102 are both configured as discontinuous structures, and the discontinuous area of one of the sub-dams is configured corresponding to the physical area of the other of the sub-dams. Therefore, not only the water blocking performance of the first sub-dam T101 and the second sub-dam T102 is maintained, but also the consumed materials and costs are reduced.

In some other embodiments, the third sub-dam T201 and the fourth sub-dam T202 may also be the continuous circular structure disposed along the edge of the display panel 10 in a circle, so as to maintain relatively desirable moisture blocking performance.

A projection shape of the second dam T2 on the second substrate 12 is annular, that is to say, the second dam T2 is disposed along the edge of the display panel 10 in a circle to form a continuous circular structure. The second dam T2 and the frame 13 disposed in a circle, as well as the discontinuously distributed first sub-dam T101 and second sub-dam T102 form a complete structure for sealing the edge of the display panel 10.

Further, the first sub-dam T101 and the second sub-dam T102 each include a first dam body T11 and a first water blocking layer T12 covering the first dam body T11. The first water blocking layer T12 is located between the first dam body T11 and the frame 13. The second dam T2 includes a second dam body T21 and a second water blocking layer T22 covering the second dam body T21. The second water blocking layer T22 is located between the second dam body T21 and the frame 13. In addition to main materials, such as rubber, the first dam body T11 and the second dam body T21 further include some desiccant materials, such as one or more of magnesium oxide, calcium oxide, magnesium chloride, or silica gel.

The first water blocking layer T12 and the second water blocking layer T22 may be water blocking materials respectively coated or deposited on sides of surfaces of the first dam body T11 and the second dam body T21, and the water blocking materials may be one or more of silicon nitride, silicon oxynitride, or aluminum oxide. The frame 13 includes a plastic frame and a desiccant distributed inside or on a surface of the plastic frame. The desiccant includes one or more of magnesium oxide, calcium oxide, magnesium chloride, or silica gel.

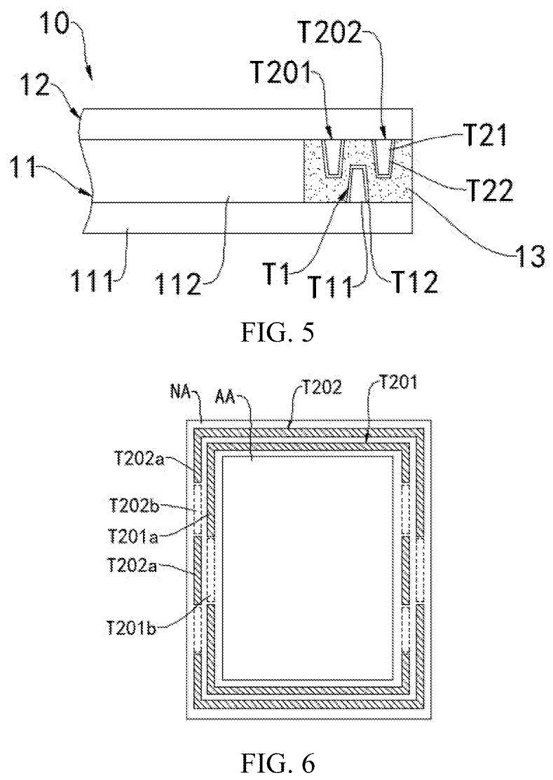

In another embodiment, referring to FIG. 5 and FIG. 6, FIG. 5 is a schematic partial cross-sectional view of a structure of a third display panel according to an embodiment of the present disclosure, and FIG. 6 is a schematic top view of a structure of a second substrate in the third display panel according to an embodiment of the present disclosure. It may be understood that the display panel provided in the present embodiment has a same or similar structure as the display panel described in the above embodiment. The features of the display panel provided in the present embodiment are described below. For details not provided, refer to the description of the above embodiment.

The present embodiment provides a display panel 10. The display panel includes a first substrate 11 and a second substrate 12 disposed opposite to the first substrate 11. The first substrate 11 includes a base substrate 111 and a display function layer 112 disposed on the base substrate 111. The second substrate 12 is disposed on a light-exit surface of the first substrate 11.

The display panel 10 has a display area AA and a non-display area NA adjacent to the display area AA. A plurality of display units are disposed in an area of the first substrate 11 corresponding to the display area AA to realize the display function. The non-display area NA is close to an edge of the display panel 10, and has disposed therein a plurality of functional elements configured to help display units in the display area AA perform displaying and a packaging structure configured to package the edge of the display panel 10.

The display panel 10 further includes a frame 13 disposed between the first substrate 11 and the second substrate 12. The frame 13 is disposed in the non-display area NA. The frame 13 is disposed along the non-display area NA and around the edge of the display panel 10 in a circle, to realize the packaging of the edge of the display panel 10.

A first dam T1 is disposed on a side of the first substrate 11 facing the second substrate 12. The first dam T1 protrudes toward the second substrate 12 and is disposed corresponding to the non-display area NA. A second dam is disposed on a side of the second substrate 12 facing the first substrate 11. The second dam includes a third sub-dam T201 and a fourth sub-dam T202 disposed parallel to each other. The third sub-dam T201 and the fourth sub-dam T202 both protrude toward the first substrate 11 and are disposed corresponding to the non-display area NA. The first dam T1 is disposed between the third sub-dam T201 and the fourth sub-dam T202, and the first dam T1, the third sub-dam T201, and the fourth sub-dam T202 are all embedded in the frame 13, so as to enhance the moisture blocking performance of the edge of the display panel 10 and reduce the risk of failure of the packaging at the edge of the display panel 10.

The third sub-dam T201 includes a plurality of third dam areas T201a discontinuously disposed and a third discontinuous area T201b located between two adjacent third dam areas T201a. The fourth sub-dam T202 includes a plurality of fourth dam areas T202a discontinuously disposed and a fourth discontinuous area T202b located between two adjacent fourth dam areas T202a. The fourth discontinuous area T202b corresponds to the third dam area T201a, and the third discontinuous area T201b corresponds to the fourth dam area T202a.

In some other embodiments, the third sub-dam T201 and the fourth sub-dam T202 may also be the continuous circular structure disposed along the edge of the display panel 10 in a circle, so as to maintain relatively desirable moisture blocking performance.

A projection shape of the first dam T1 on the first substrate 11 is annular, that is, the first dam T1 is disposed along the edge of the display panel 10 in a circle to form a continuous circular structure. The first dam T1 and the frame 13 disposed in a circle, as well as the discontinuously distributed third sub-dam T201 and fourth sub-dam T202 form a complete structure for sealing the edge of the display panel 10.

Further, the first dam T1 includes a first dam body T11 and a first water blocking layer T12 covering the first dam body T11. The first water blocking layer T12 is located between the first dam body T11 and the frame 13. The third sub-dam T201 and the fourth sub-dam T202 each include a second dam body T21 and a second water blocking layer T22 covering the second dam body T21. The second water blocking layer T22 is located between the second dam body T21 and the frame 13. In addition to main materials, such as rubber, the first dam body T11 and the second dam body T21 further include some desiccant materials, such as one or more of magnesium oxide, calcium oxide, magnesium chloride, or silica gel.

The first water blocking layer T12 and the second water blocking layer T22 may be water blocking materials respectively coated or deposited on sides of surfaces of the first dam body T11 and the second dam body T21, and the water blocking materials may be one or more of silicon nitride, silicon oxynitride, or aluminum oxide. The frame 13 may further include a plastic frame and a desiccant distributed inside or on a surface of the plastic frame. The desiccant includes one or more of magnesium oxide, calcium oxide, magnesium chloride, or silica gel.

In conclusion, according to the display panel provided in embodiments of the present disclosure, the first dam and the second dam corresponding to the non-display area at the edge of the display panel are respectively disposed on the first substrate and the second substrate, and the first dam and the second dam are arranged adjacent to each other, and are both embedded in the frame of the display panel. By means of the embedded structure of the first dam, the second dam, and the frame, the moisture blocking performance of the edge of the display panel is enhanced, the moisture intruding path into the display panel is extended, and the risk of failure of the packaging at the edge of the display panel is reduced.

It should be noted that, although the present disclosure is disclosed above with reference to the specific embodiments, the foregoing embodiments are not intended to limit the present disclosure. A person of ordinary skill in the art may make various variations and modifications without departing from the spirit and scope of the present disclosure. Therefore, the protection scope of the present disclosure is defined by the appended claims.

What is claimed is:

1. A display panel, comprising:
a first substrate comprising a display area having a plurality of display units and a non-display area adjacent to the display area and close to an edge of the first substrate, wherein a first dam is disposed in an area of the first substrate corresponding to the non-display area;
a second substrate disposed opposite to the first substrate, wherein a second dam is disposed in an area of the second substrate corresponding to the non-display area, the first dam protrudes toward the second substrate, the second dam protrudes toward the first substrate, and the first dam and the second dam are arranged adjacent to each other; and
a frame disposed between the first substrate and the second substrate and corresponding to the non-display area, wherein the first dam and the second dam are both embedded in the frame.

2. The display panel as claimed in claim 1, wherein a projection of the first dam on the first substrate is annular, and a projection of the second dam on the second substrate is annular.

3. The display panel as claimed in claim 2, wherein the first dam and the second dam are both disposed along an edge of the display panel in a circle.

4. The display panel as claimed in claim 2, wherein the first dam comprises a square circular structure or an annular structure, and the second dam comprises a square circular structure or an annular structure.

5. The display panel as claimed in claim 1, wherein a projection of the first dam on the second substrate and the second dam partially overlap or do not overlap.

6. The display panel as claimed in claim 1, wherein a height of the first dam is less than a total thickness of the frame and is greater than half of the thickness of the frame, and a height of the second dam is also less than a total thickness of the frame and is greater than half of the thickness of the frame.

7. The display panel as claimed in claim 1, wherein the first dam comprises a first sub-dam and a second sub-dam disposed parallel to each other, wherein the second dam is disposed between the first sub-dam and the second sub-dam.

8. The display panel as claimed in claim 7, wherein the first sub-dam comprises a plurality of first dam areas discontinuously disposed and a first discontinuous area located between two adjacent first dam areas, and the second sub-dam comprises a plurality of second dam areas discontinuously disposed and a second discontinuous area located between two adjacent second dam areas; and
the second discontinuous area corresponds to the first dam area, and the first discontinuous area corresponds to the second dam area.

9. The display panel as claimed in claim 1, wherein the second dam comprises a third sub-dam and a fourth sub-dam disposed parallel to each other, wherein the first dam is disposed between the third sub-dam and the fourth sub-dam.

10. The display panel as claimed in claim 9, wherein the third sub-dam comprises a plurality of third dam areas discontinuously disposed and a third discontinuous area located between two adjacent third dam areas, and the fourth sub-dam comprises a plurality of fourth dam areas discontinuously disposed and a fourth discontinuous area located between two adjacent fourth dam areas, wherein
the fourth discontinuous area corresponds to the third dam area, and the third discontinuous area corresponds to the fourth dam area.

11. The display panel as claimed in claim 1, wherein a cross-sectional shape of the first dam along a plane perpendicular to the first substrate comprises a trapezoid or a triangle.

12. The display panel as claimed in claim 1, wherein a cross-sectional shape of the second dam along a plane perpendicular to the second substrate comprises a trapezoid or a triangle.

13. The display panel as claimed in claim 1, wherein the first dam comprises a first dam body and a first water blocking layer covering the first dam body, wherein the first water blocking layer is located between the first dam body and the frame.

14. The display panel as claimed in claim 1, wherein the second dam comprises a second dam body and a second water blocking layer covering the second dam body, wherein the second water blocking layer is located between the second dam body and the frame.

15. The display panel as claimed in claim 14, wherein the first dam body comprises one or more of magnesium oxide, calcium oxide, magnesium chloride, or silica gel, and the first water blocking layer comprises one or more of silicon nitride, silicon oxynitride, or aluminum oxide.

16. The display panel as claimed in claim 14, wherein the second dam body comprises one or more of magnesium oxide, calcium oxide, magnesium chloride, or silica gel, and the second water blocking layer comprises one or more of silicon nitride, silicon oxynitride, or aluminum oxide.

17. The display panel as claimed in claim 1, wherein the frame comprises a plastic frame and a desiccant distributed inside or on a surface of the plastic frame.

18. The display panel as claimed in claim 17, wherein the desiccant comprises one or more of magnesium oxide, calcium oxide, magnesium chloride, or silica gel.

19. The display panel as claimed in claim 1, wherein the frame is disposed along the non-display area and around the edge of the display panel in a circle.

20. A display panel, comprising:
a first substrate comprising a display area having a plurality of display units and a non-display area adjacent to the display area and close to an edge of the first substrate, wherein a first dam is disposed in an area of the first substrate corresponding to the non-display area;
a second substrate disposed opposite to the first substrate, wherein a second dam is disposed in an area of the second substrate corresponding to the non-display area, the first dam protrudes toward the second substrate, the second dam protrudes toward the first substrate, and the first dam and the second dam are arranged adjacent to each other; and
a frame disposed between the first substrate and the second substrate and corresponding to the non-display area, wherein the first dam and the second dam are both embedded in the frame; wherein
a height of the first dam is less than a total thickness of the frame and is greater than half of the thickness of the frame, a height of the second dam is also less than a total thickness of the frame and is greater than half of the thickness of the frame, and a projection of the first dam on the second substrate and the second dam partially overlap or do not overlap.
